(19) United States
(12) Patent Application Publication
(10) Pub. No.: US 2025/0006870 A1
(43) Pub. Date: Jan. 2, 2025

(54) OPTICAL FILTERING FOR SEMICONDUCTOR DEVICE PACKAGING

(71) Applicant: TEXAS INSTRUMENTS INCORPORATED, DALLAS, TX (US)

(72) Inventors: Steven KUMMERL, CARROLLTON, TX (US); Sparsh BALABADRAPATRUNI, ROCKWALL, TX (US); Daniel FLINT, CARROLLTON, TX (US)

(21) Appl. No.: 18/345,477

(22) Filed: Jun. 30, 2023

(51) Int. Cl. H01L 33/50; H01L 33/52

(52) U.S. Cl. CPC H01L 33/502; H01L 33/52; H01L 2933/005

(57) ABSTRACT

An example electronic device including a semiconductor die and a mold compound overlying the die, and the mold compound is chemically altered to attenuate electromagnetic radiation within a range of wavelengths or frequencies.

### TECHNICAL FIELD

This description relates to optical filtering for semiconductor device packaging.

### BACKGROUND

Various types of optical semiconductor devices have been developed. For example, photodetectors, such as photodiodes, photoresistors and phototransistors, are configured to sense light or other electromagnetic radiation. Other types of optical semiconductor devices, such as light emitting diodes (LEDs), are configured to emit light or other electromagnetic radiation. In some applications, it is desirable to control (or filter) the wavelength of electromagnetic radiation that can propagate to and/or from the devices. Accordingly, pigments have been incorporated into packaging materials or optical coatings can be applied on device packaging to implement optical filters for semiconductor devices.

### SUMMARY

In described examples, a method includes providing a semiconductor die and a layer of mold compound overlying the semiconductor die. The method also includes chemically altering the mold compound to attenuate electromagnetic radiation within a range of wavelengths or frequencies.

In another described example, an electronic device includes a semiconductor die and a mold compound overlying the semiconductor die. The mold compound is chemically altered to attenuate electromagnetic radiation within a range of wavelengths or frequencies.

In yet another example, a packaged electronic device includes a semiconductor die having opposing first and second side surfaces, in which the semiconductor die includes circuitry adjacent the first side surface. The packaged device also includes mold compound overlying at least the first side surface of the semiconductor die including the circuitry, in which the mold compound is chemically altered to attenuate propagation of electromagnetic energy within a range of wavelengths or frequencies through the chemically-altered mold compound overlying the circuitry.

### BRIEF DESCRIPTION OF THE DRAWINGS

FIG. 1 is a flow diagram depicting an example method of chemically altering a mold compound of a semiconductor device.

FIG. 2 is a flow diagram depicting an example method of backend processing to make a semiconductor device.

FIG. 3 is schematic diagram of a system configured to chemically alter a mold compound of a semiconductor device.

FIG. 4 is an isometric view of an example wafer having a chemically-altered mold compound.

FIG. 5 is a side sectional view of an example packaged semiconductor device.

FIG. 6 is a side sectional view of another example packaged semiconductor device.

FIG. 7 is an isometric view of another example packaged semiconductor device.

FIG. 8 is a graph showing examples of transmissibility as a function of wavelength for different amounts of irradiation applied to a mold compound.

FIGS. 9A and 9B are graphs showing absorption characteristics of an epoxy material before and after irradiation, respectively.

### DETAILED DESCRIPTION

This description relates to optical filtering for semiconductor device packaging, such as chemically altering a packing material of the semiconductor device.

As an example, a semiconductor device includes one or more semiconductor dies and a layer of mold compound overlying the die(s). The mold compound is chemically altered to attenuate (e.g., block) electromagnetic radiation within a range of wavelengths or frequencies. For example, the mold compound is chemically altered by applying an ionizing radiation (e.g., gamma radiation) to the mold compound to shift a passband of the mold compound to longer wavelengths of electromagnetic radiation. The semiconductor device can include one or more optical circuit components within the die configured to operate with the passband of the chemically altered mold compound. In an example, the die includes optical circuitry (e.g., a photodetector) that is configured to sense electromagnetic radiation outside of the range of wavelengths or frequencies that have been attenuated. In another example, the die includes optical circuitry (e.g., a light source) configured to emit light and the semiconductor device is thus configured to provide light from the mold compound having a wavelength outside of the range of wavelengths that have been attenuated. By chemically altering the mold compound to implement optical filtering in this manner, optical devices can be produced to operate with as high or higher performance and at lower cost than many existing devices. Additionally, the approach described herein is scalable

As used herein, the term chemically altered (and its variants) refers to a physical change in the structure of a material, such as a mold compound. For example, the ionizing radiation (e.g., gamma rays) is applied to a mold compound to alter the physical properties of the mold compound at a molecular and/or quantum level and modify the optical passband of the mold compound (e.g., change the frequencies or wavelengths of electromagnetic radiation that can pass through the mold compound). The ionizing radiation applied to the mold compound can form free radical species within the mold compound, which are unstable and tend to form bonds with other species present. The formation of free radical in the mold compound thus can lead to the scission of bonds, crosslinking, and other reactions that could happen due to the formation of free radicals. The free radical species can react with oxygen (e.g., photooxidation) to change the optical and mechanical properties of the mold compound, in which the altered crystallinity and the new bonds formed cause the mold compound to absorb and transmit different wavelengths of light.

In one example, an original mold compound (before being chemically altered) is translucent to light in both the visible spectrum and infrared spectrum, and a chemically altered version of such mold compound is adapted to attenuate (or be opaque to) light in the visible spectrum and be translucent to light infrared spectrum. The resulting passband (or passbands) to which the chemically altered mold compound is shifted can vary depending on the type and/or extent of chemical alteration that is implemented on the mold compound. Therefore, the chemical alteration of the mold compound, as described herein, differs from the use of pigments, which tend to be insoluble and are usually finely ground particles that are mixed with the mold compound before being applied to the semiconductor device.

Also, as used herein, the term semiconductor device (and its variants) refers to any structure or apparatus that includes a semiconductor substrate. For example, a semiconductor substrate (e.g., a wafer) having a plurality of integrated circuit (IC) dies formed thereon is a semiconductor device. An individual die or group of die, which may be on a wafer or separated from the wafer, is another example of a semiconductor device. Additionally, one or more dies that have been packaged in molding material is yet another example of a semiconductor device. Thus, a semiconductor device can exist at any stage of the semiconductor fabrication workflow including the wafer with encapsulation layer as well as the resulting packaged IC chip or packaged system on chip (SOC).

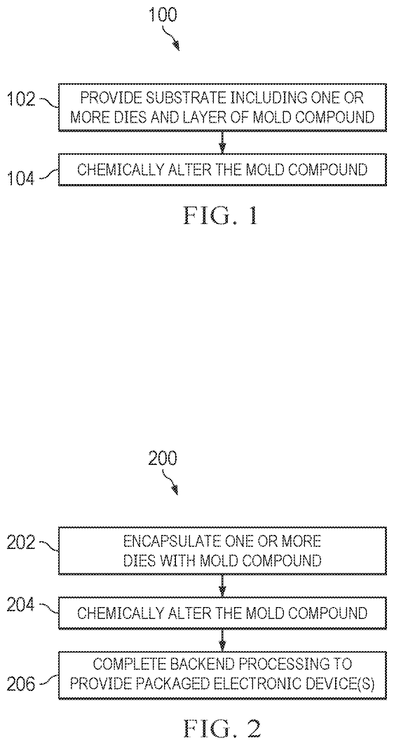

FIG. 1 is a flow diagram depicting an example method 100 of chemically altering an electronic device to exhibit modified optical properties. At 102, the method includes providing a substrate having one or more dies and a mold compound over the die(s). In one example the substrate is a wafer prior to die separation, in which the wafer includes a plurality of dies distributed across a respective side of the wafer. In another example, the substrate is a die after die separation, and the die can be mounted to a lead frame depending on the type of package being formed. Regardless of the form of the substrate at 102, the die includes circuitry formed thereon as part of a front end processing of a semiconductor fabrication process, of which the method 100 can be part. In some examples, the circuitry includes one or more circuit components configured to be responsive to light, such as a photodetector (e.g., photodiode, photoresistor, phototransistor etc.). In addition, or as an alternative, the circuitry includes one or more circuit components configured to provide light, such as an LED.

As described herein, mold compound is over the respective dies. The mold compound can include one or more layers of material that are chemically altered responsive to ionizing irradiation. Examples of materials that can be used to form the mold compound, individually or in combination, include ultra-high-molecular-weight Polyethylene (UHMWPE), polyaniline (PANI), polytetrafluoroethylene (PTFE), Poly (3-hydroxybutylate) (PHB), Polyethylene terephthalate (PET), and epoxy resin. In some examples, the mold compound can include one or more filler materials, such as can be configured to help tune coefficient of thermal expansion and/or modulus of elasticity. Examples of some fillers include fused silica (SiO₂), polyphenylene-oxide/silica, such as in spherical and/or “fiber glass” form. Additionally, or alternatively, brown carbon/black carbon filler materials can be used to absorb more visible ranges and enable propagation of IR bands. As yet another example, Al₂O₃ can be used to block UV and allow visible and IR to transmit through the mold compound, which can even be coated onto other materials to add more selectivity on the optical band pass. Other filler materials can be used in other examples.

At 104, the method includes chemically altering the mold compound. For example, the chemical alteration can be implemented by applying ionizing radiation to the mold compound. The dosage of irradiation can vary depending on the intensity and the intensity can further vary based on the source of ionizing radiation. In one example, a minimum dosage of ionizing radiation is about 5 kGy (e.g., the dosage can be 5 kGy or higher). In another example, the dosage ranges from about 10 kGy to about 500 kGy. In yet another example, the dosage of ionizing radiation ranges from about 50 kGy to about 100 kGy. Other dosages can be used in other examples. The selected dosage or range of dosages can be chosen depending on a desired wavelength (or range of wavelengths) of light to be attenuated by the mold compound and/or to be within the passband of the mold compound. The dosage can also determine the amount of light absorbed by the mold compound. The dosage of ionizing radiation can further vary as a function of the emission source(s), the type of mold compound, and/or thickness of the mold compound. By implementing the method 100, a semiconductor device can be provided with a chemically altered mold compound overlying optical circuitry of one or more dies of a semiconductor device.

FIG. 2 is a flow diagram of another method 200 that can be implemented for making a semiconductor device, such as an IC chip or an SOC device. The method 200 describes part of backend processing of a semiconductor fabrication process, in which features of the process not shown or described can be implemented according to any suitable process steps according to the type of circuitry and package desired for a respective application.

In the example method 200 of FIG. 2, at 202 the method includes encapsulating one or more dies with one or more mold compound. The mold compound can be or include a material that is optically translucent to electromagnetic radiation within a range of wavelengths. In some examples, the mold compound includes one or more filler materials, which can affect subsequent processing (e.g., at 204) and/or affect (e.g., increase or decrease) the range of wavelengths that can propagate through the mold compound). In one example, the die(s) are singulated dies after die separation (e.g., cutting and/or laser dicing process), which may or may not have been mounted to a lead frame. In another example, a plurality of dies is on a wafer prior to die separation. The dies include circuitry having one or more optical circuit components (e.g., photodetectors and/or light sources), such as described herein.

At 204, the mold compound is chemically altered, such as by applying an ionizing radiation (e.g., gamma radiation). As described herein, the ionizing radiation can be applied at a dosage and for a duration that can depend on a type and/or thickness of the mold compound as well as the extent of chemical alteration being sought for the mold compound. In some examples, the ionizing radiation is applied uniformly across an exposed surface of the mold compound. In other examples, the ionizing radiation can be focused discriminately (e.g., a beam of radiation) at particular locations across the exposed surface of the mold compound. The mold compound can thus be chemically altered at 204 to absorb and/or transmit different wavelengths of light than prior to being chemically altered. As one example, the mold compound applied at 202 can be translucent to light in both the visible spectrum and infrared spectrum, and the chemically altered version of such mold compound (after altering at 204) is adapted to attenuate (or be opaque to) light in the visible spectrum and be translucent to light infrared spectrum. Different changes in wavelengths that are attenuated versus being transmissible through the mold compound can be achieved in other examples, such as by adding one or more fillers to mold compound and/or changing the dosage parameters used for applying the ionizing radiation.

At 206, backend processing is completed to provide respective semiconductor devices. For example, the backend processing can include die separation, testing and/or any other process steps used to complete formation of a packaged semiconductor device. The backend processing at 206 can vary depending on the form of the semiconductor device that is encapsulated at 202, namely, whether the respective dies have been singulated or are on a wafer. Additional backend processing variations can be used if the die is attached to a lead frame or if the device is a leadless device. Final part of the processing at 206 can involve testing of the packaged devices that are provided by the method 200.

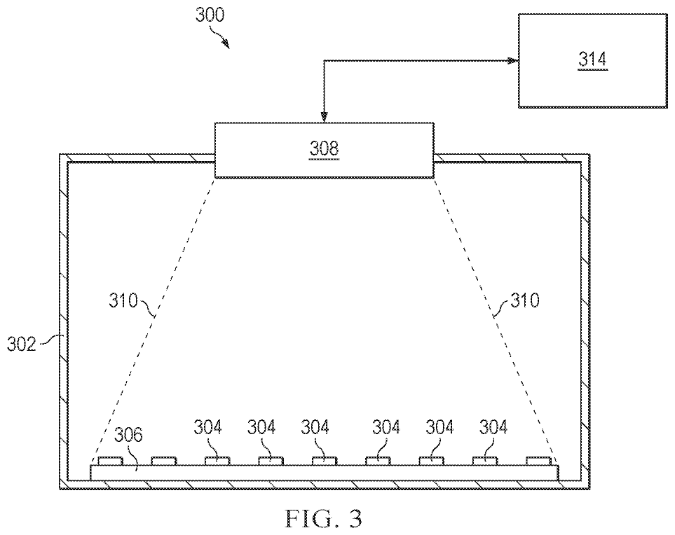

FIG. 3 is a schematic diagram of a system 300 configured to chemically alter a mold compound for a semiconductor device. The system 300 includes a chamber 302 having an interior volume configured to receive one or more objects to be irradiated. The chamber 302 can include shielded walls configured to prevent radiation from escaping from the chamber. In the example of FIG. 3, the objects include one or more semiconductor devices 304, which can be placed within the interior volume of the chamber 302. The semiconductor devices 304 can be placed on a support 306, such as a floor or other structure within the chamber 302, to hold the semiconductor devices at a position spaced a distance from a radiation source 308. The support can be fixed within the chamber or be movable, such as including a conveyor system, to automatically move the semiconductor devices 304 into the chamber 302 for irradiation. The distance between the radiation source and a surface of the semiconductor devices 304 can be known a priori or the distance can be determined at the time of irradiation (e.g., by measuring, automatically or manually).

The radiation source 308 is configured to provide ionizing radiation, shown at 310, based on a set of one or more control parameters. For example, the control parameters can include an intensity, duration and wavelength of the ionizing radiation. Additionally, or alternatively, one or more such parameters can specify a dose or measure of radiation absorbed by the semiconductor devices 304 (e.g., from about 5 kGy to about 500 kGy), such as described herein. In an example, the radiation source 308 is configured to provide the ionizing radiation to include gamma radiation (e.g., from cobalt-60). In other examples, the radiation source 308 is configured to provide the ionizing radiation as electrons or x-rays.

The system 300 can also include a control system 314 configured to control the radiation source 308. For example, the control system 314 can set one or more parameters to control the ionizing radiation based on the semiconductor devices placed in chamber 302 and the chemical alteration to be achieved responsive to the irradiation. The control system 314 can include a terminal or other user interface device (e.g., keyboard, mouse, touch screen or the like) and a user can set the control parameters in response to a user input at the terminal or user interface device. In an example, the parameters can include attributes or properties of the irradiation, such as energy level (e.g., intensity), wavelength of radiation, and duration. In another, or alternative example, the control parameters can include or be derived from attributes or properties of the semiconductor devices 304, such as the number and type of semiconductor devices, the type of mold compound, material composition of the mold compound, thickness of the mold compound, distance between the radiation source 308 and the semiconductor devices, and the like. The control parameters further may vary based on environmental conditions, such as temperature, pressure, humidity, and the like.

As described herein, the control system 314 is configured to control the radiation source 308 to emit the ionizing radiation 310 onto the semiconductor devices 304 and chemically alter the mold compound thereof. For example, the ionizing radiation forms free radical species amongst the materials that form the mold compound (e.g., polymers, epoxy, etc.). The free radical species can bond with other species present, leading to the scission of bonds, crosslinking, and/or other reactions that can alter the crystallinity of the mold compound. The altered crystallinity and the new bonds formed can allow the mold compound to absorb and transmit different wavelengths of light. Additionally, the free radicals can cause photooxidation, which changes the optical and mechanical properties of the mold compound.

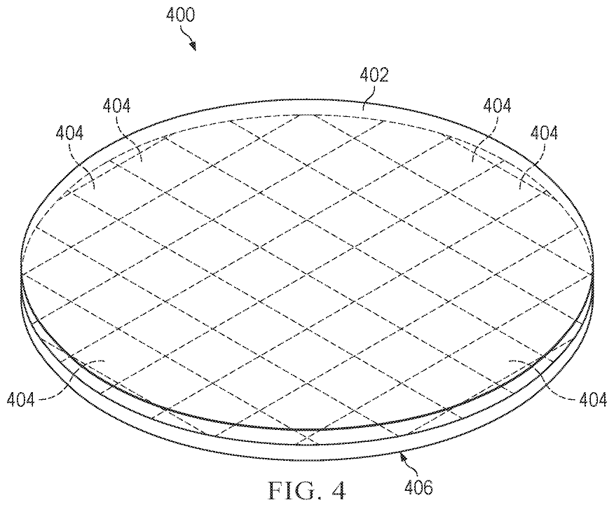

FIGS. 4, 5, 6 and 7 depicts examples of different semiconductor devices, such as can be provided by the methods and/or systems described herein (e.g., methods 100 or 200, or system 300). Other types and configurations of semiconductor devices can be provided based on this disclosure.

FIG. 4 is an isometric view of an example semiconductor device (e.g., a wafer before die separation) 400 having a chemically altered mold compound 402 on a respective side of the wafer and having a pass band for a range of wavelengths of electromagnetic radiation. For example, the semiconductor device 400 includes a plurality of dies 404, which can be formed in a semiconductor substrate 406 according to a respective front-end semiconductor fabrication process. Each of the dies 404 thus includes circuitry configured to perform one or more circuit functions. As described herein, the circuitry on each die 404 can include one or more optical circuit components that operate within a range of wavelengths that is within the pass band of the chemically altered mold compound 402.

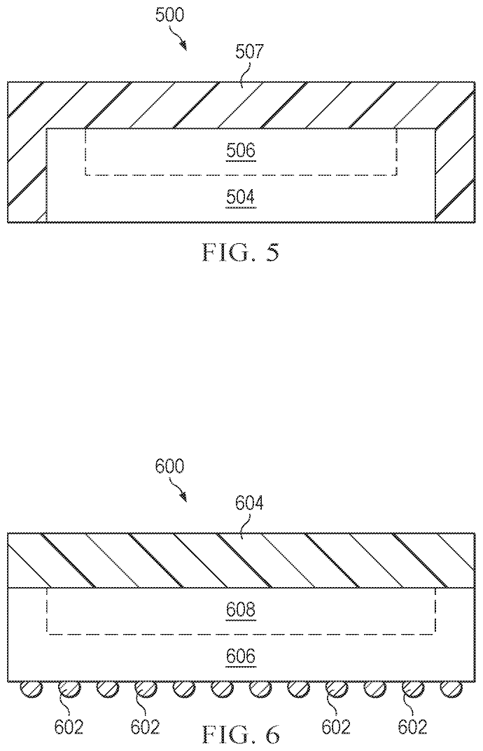

FIG. 5 is a side sectional view of an example packaged semiconductor device 500. The semiconductor device 500 thus includes a mold compound 502 over a die 504, such as has been singulated from a wafer. The semiconductor device 500 can include any number of dies. For example, the semiconductor device 500 can be a leadless device, such as a quad-flat no-leads (QFN), dual-flat no-leads (DFN) package type. The die 504 includes circuitry 506 configured to perform one or more circuit functions. As described herein, the circuitry 506 on the die 504 can include one or more optical circuit components configured to operate over a range of wavelengths that is within a pass band of the chemically altered mold compound 502. External contacts have been omitted from the packaged semiconductor device 500 shown in FIG. 5 for clarity reasons. The semiconductor device 500 thus can include an arrangement of external contacts, which can be provided through a traditional punched leadframe, or routable leadframe, or bumps can be formed on respective contacts on the die 504 which exit the bottom surface of packaged semiconductor device 500.

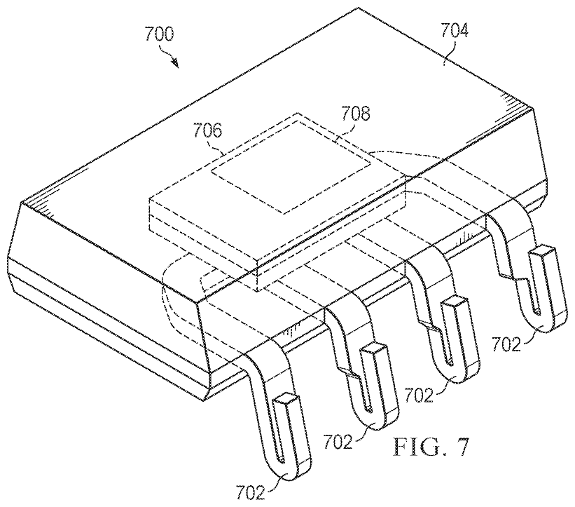

FIG. 6 is a side sectional view of yet another example type of packaged semiconductor device 600 that includes bumps or solder balls 602 on respective pads of a surface thereof. For example, the semiconductor device 600 can be a flip chip module. The semiconductor device 600 includes a mold compound 604 over a die 606. The semiconductor device 600 can include any number of dies. The die 606 includes circuitry 608 configured to perform one or more circuit functions. As described herein, the circuitry 608 can include one or more optical circuit components configured to operate over a range of wavelengths that is within a pass band of the chemically altered mold compound 604.

FIG. 7 is an isometric view of another example type of packaged semiconductor device 700 that includes an arrangement of leads 702 along one or more edges of thereof. For example, the semiconductor device 700 can be any leaded device, such as a single in-line package, dual in-line package, quad in-line package or the like. The semiconductor device 700 includes a mold compound 704 over a die 706. The semiconductor device 700 can include any number of dies. The die 706 includes circuitry 708 configured to perform one or more circuit functions. As described herein, the circuitry 708 can include one or more optical circuit components (e.g., photodetectors or light sources) configured to operate over a range of wavelengths that is within a pass band of the chemically altered mold compound 704.

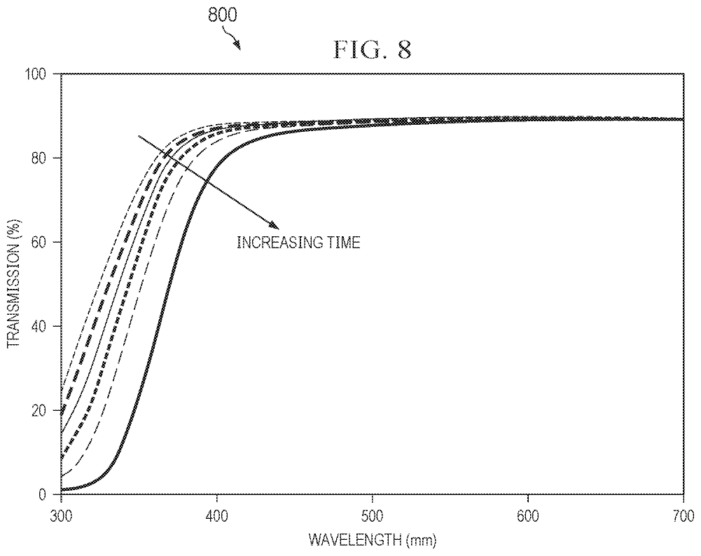

FIG. 8 is a graph 800 illustrating examples of transmissibility of light through a mold compound as a function of wavelength. The graph 800 demonstrates that increasing the amount of time a mold compound is treated with a given dose of ionizing radiation can decrease the transmission of light. Stated differently, shorter wavelengths of light are attenuated more readily by ionizing radiation, whereas longer wavelengths tend to retain their transmissibility.

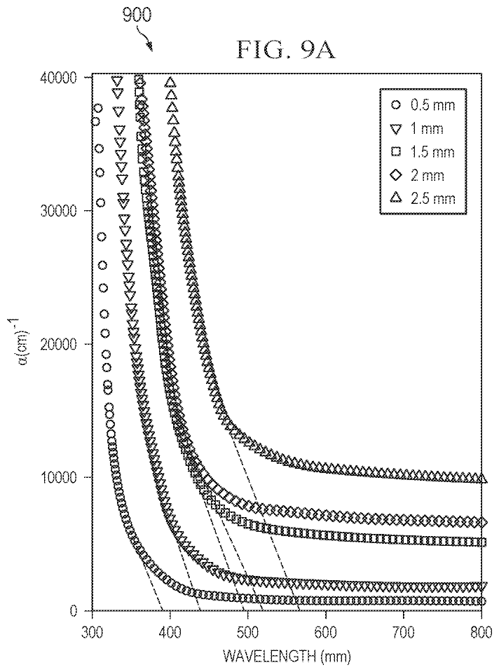

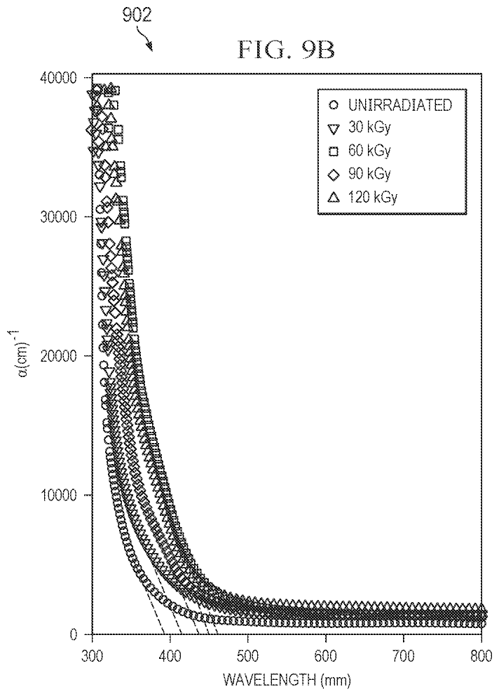

FIGS. 9A and 9B are graphs 900 and 902 showing examples of absorption characteristics of an epoxy material before and after irradiation, respectively. The graph 900 of FIG. 9A shows the absorption characteristics of non-irradiated epoxy thin films ranging from 0.5 mm thickness to 2.5 mm thickness over a range of wavelengths. The graph 902 of FIG. 9B absorption characteristics of an irradiated epoxy thin films, each having a 0.5 mm thickness for different amounts of irradiation, ranging from unirradiated to 120 kGy. Thus the shift in absorption demonstrates that thinner mold compounds can be irradiated and used in place of thicker unirradiated materials to achieve similar optical performance characteristics.

In view of the foregoing, systems and methods can implement chemically altered mold compound materials to achieve optical filtering in semiconductor devices having similar or enhanced performance at a reduced cost compared to existing approaches that use expensive inorganic filler particles or sputtered thin films for filtering. Additionally, the approach described herein provides a scalable process for mold compound alteration that can be implemented easily into existing process flows and back end processing.

In this description, the term “couple” or “couples” means either an indirect or direct connection. Thus, if a first device couples to a second device, that connection may be through a direct connection or through an indirect connection via other devices and connections. For example, if device A generates a signal to control device B to perform an action, then: (a) in a first example, device A is coupled to device B; or (b) in a second example, device A is coupled to device B through intervening component C if intervening component C does not alter the functional relationship between device A and device B, so device B is controlled by device A via the control signal generated by device A.

Also, in this description, a device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof. Furthermore, a circuit or device described herein as including certain components may instead be configured to couple to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor wafer and/or integrated circuit (IC) package) and may be configured to couple to at least some of the passive elements and/or the sources to form the described structure, either at a time of manufacture or after a time of manufacture, such as by an end user and/or a third party.

The recitation “based on” means “based at least in part on.” Therefore, if X is based on Y, X may be a function of Y and any number of other factors.

Modifications are possible in the described embodiments, and other embodiments are possible, within the scope of the claims.

What is claimed is:

1. A method comprising:
providing a semiconductor die and a layer of mold compound overlying the semiconductor die; and
chemically altering the mold compound to attenuate electromagnetic radiation within a range of wavelengths or frequencies.

2. The method of claim 1, wherein chemically altering comprises applying an ionizing radiation to the mold compound to shift a passband of the mold compound to longer wavelengths of electromagnetic radiation.

3. The method of claim 2, wherein the ionizing radiation comprises gamma radiation.

4. The method of claim 2, wherein the ionizing radiation is applied to the mold compound at a dose ranging from 5 kGy to 500 kGy.

5. The method of claim 1, wherein the semiconductor die comprises circuitry configured to operate responsive to electromagnetic radiation outside of the range of wavelengths or frequencies.

6. The method of claim 5, wherein the circuitry comprises a photodetector.

7. The method of claim 5, wherein the circuitry comprises a light source configured to provide electromagnetic radiation, in which electromagnetic radiation outside of the range of wavelengths or frequencies propagates through the mold compound and electromagnetic radiation within the range of wavelengths or frequencies is attenuated by the chemically-altered mold compound.

8. The method of claim 1, wherein the range of wavelengths or frequencies includes visible light.

9. The method of claim 1, wherein a plurality of semiconductor dies are distributed across an active side of a semiconductor wafer, and the method further comprises:
applying the mold compound on the active side of the wafer over the plurality of semiconductor dies.

10. The method of claim 1, wherein the semiconductor die and the mold compound overlying the die form a packaged integrated circuit (IC) or system on chip (SOC) device having circuitry along an active side of the die, and the mold compound of the IC or SOC is chemically altered to shift a passband of the mold compound to longer wavelengths of electromagnetic radiation.

11. An electronic device comprising:
a semiconductor die; and
a mold compound overlying the semiconductor die, in which the mold compound is chemically altered to attenuate electromagnetic radiation within a range of wavelengths or frequencies.

12. The electronic device of claim 11, wherein the semiconductor die comprises circuitry configured to operate responsive to electromagnetic radiation outside of the range of wavelengths or frequencies.

13. The electronic device of claim 12, wherein the circuitry comprises a photodetector.

14. The electronic device of claim 11, wherein the semiconductor die comprises circuitry including a light source configured to provide electromagnetic radiation, in which electromagnetic radiation outside of the range of wavelengths or frequencies propagates through the chemically-altered mold compound and electromagnetic radiation within the range of wavelengths or frequencies is attenuated by the chemically-altered mold compound.

15. The electronic device of claim 11, wherein the range of wavelengths or frequencies includes visible light.

16. The electronic device of claim 11, wherein:
the semiconductor die has an active side and an opposing side, and
the chemically-altered mold compound is on the active side of the semiconductor die.

17. The electronic device of claim 11, wherein:
the semiconductor die is a packaged integrated circuit or system on chip device having circuitry along an active side of the semiconductor die, and
the chemically-altered mold compound is on the active side of the semiconductor die and configured to shift a passband of the mold compound to different wavelengths of electromagnetic radiation.

18. A packaged electronic device, comprising:
a semiconductor die having opposing first and second side surfaces, in which the semiconductor die includes circuitry adjacent the first side surface; and
a mold compound on the semiconductor die overlying at least the first side surface of the semiconductor die including the circuitry, in which the mold compound is chemically altered to attenuate propagation of electromagnetic energy within a range of wavelengths or frequencies through the chemically-altered mold compound overlying the circuitry.

19. The packaged electronic device of claim 18, wherein the circuitry comprises a photodetector configured to operate responsive to electromagnetic energy outside of the range of wavelengths or frequencies.

20. The packaged electronic device of claim 18, wherein the circuitry includes a light source configured to provide electromagnetic radiation, in which electromagnetic radiation outside of the range of wavelengths or frequencies propagates through the chemically-altered mold compound and electromagnetic radiation within the range of wavelengths or frequencies is attenuated by the chemically-altered mold compound.
